(19) United States
(12) Patent Application Publication
(10) Pub. No.: US 2022/0311439 A1
(43) Pub. Date: Sep. 29, 2022

(54) MULTIPLEXER CIRCUIT USING A TRANSMISSION GATE CIRCUIT WITH A SELECTIVELY BOOSTED SWITCH CONTROL SIGNAL

(71) Applicant: STMicroelectronics International N.V., Geneva (CH)

(72) Inventors: Ramji GUPTA, Jhansi (IN); Anand KUMAR, Noida (IN)

(73) Assignee: STMicroelectronics International N.V., Geneva (CH)

(21) Appl. No.: 17/701,870

(22) Filed: Mar. 23, 2022

Related U.S. Application Data
(60) Provisional application No. 63/165,227, filed on Mar. 24, 2021.

(51) Int. Cl. H03K 17/693; H03K 17/687; H03K 17/06; H03K 19/20

(52) U.S. Cl. CPC H03K 17/693; H03K 17/6871; H03K 17/063; H03K 19/20; H03K 2217/0054

(57) ABSTRACT

A transmission gate circuit for use, for example, as a switching element of an analog multiplexer, includes an input configured to receive an input signal, an output and a control input configured to receive a switch control signal. A transmission gate switch is coupled between the input and the output. A level shifting circuit generates a level shifted switch control signal from the switch control signal, and applies that level shifted switch control signal to a control terminal of the transmission gate switch. The control terminal of the transmission gate switch can instead receive the switch control signal in situations where a voltage of the input signal is suitably high to support linear operation of the transmission gate switch.

### CROSS-REFERENCE TO RELATED APPLICATION

This application claims priority from U.S. Provisional Application for Patent No. 63/165,227, filed Mar. 24, 2021, the disclosure of which is incorporated by reference.

### TECHNICAL FIELD

The present invention generally relates to integrated circuit devices and, in particular, to a multiplexer circuit.

### BACKGROUND

Reference is made to FIG. 1 which shows a circuit diagram for a transmission gate switch 10. The transmission gate switch 10 includes an input node 12 and an output node 14. The input node 12 is configured to receive an input signal IN. The transmission gate switch 10 functions to selectively pass the input signal IN to produce an output signal OUT at the output node 14.

An n-channel metal oxide semiconductor field effect transistor (MOSFET) device 16 has a drain terminal coupled, preferably directly connected, to the input node 12 and a source terminal coupled, preferably directly connected, to the output node 14. The gate terminal of the n-channel MOSFET device 16 is coupled to receive a switch control signal SW. A p-channel MOSFET device 18 has a drain terminal coupled, preferably directly connected, to the input node 12 and a source terminal coupled, preferably directly connected, to the output node 14. The MOSFET devices 16 and 18 are, thus, connected in parallel with each other. The gate terminal of the p-channel MOSFET device 18 is coupled to receive a logical inverse (SWB) of the switch control signal SW. The logical inverse switch control signal SWB may be generated, for example, by a logical inverter circuit 20 from the switch control signal SW.

Operation of the transmission gate switch 10 is as follows: in response to the switch control signal SW being in a first (for example, low) logic state, transistors 16 and 18 are both turned off, and the transmission gate switch 10 functions as an open switch blocking passage of the signal at the input node 12 from reaching the output node 14. Conversely, in response to the switch control signal SW being in a second (for example, high) logic state, transistors 16 and 18 are both turned on, and the transmission gate switch 10 functions as a closed switch permitting passage of the signal at the input node 12 to the output node 14.

FIG. 2 shows a graph plotting resistivity of the transmission gate switch 10 in the closed switch state as a function of voltage of the input signal IN at the input node 12. It will be noted that the resistivity is highly dependent on input signal voltage level. For an analog input signal IN having a wide voltage swing, this dependency can adversely affect signal quality of the output signal OUT. A more linear response of the transmission gate switch 10 would be an advantage. This can be achieved, for example, by instead using a bootstrapped switch (see, B. Razavi, “The Bootstrapped Switch,” IEEE Solid-State Circuits Magazine, Summer 2015, incorporated by reference) in place of the transmission gate switch 10. The bootstrapped switch requires a capacitance for better linearity, but a drawback of this is a corresponding increase in occupied circuit area on the integrated circuit die. Leakage current is also a concern, which prompts selection of a larger capacitance value. These issues become even more significant when the bootstrapped switch is used as the selectively actuated switching element of an analog multiplexer circuit.

It would be advantageous to instead use the transmission gate switch 10 for such an analog multiplexer circuit. Reference is now made to FIG. 3 which shows a circuit diagram for an analog multiplexer (MUX) circuit 21 that uses selectively actuated transmission gate switches 10. The MUX circuit 21 includes N input nodes 22(0)-22(N−1) and an output node 24. Each input node 22 is configured to receive a corresponding analog input signal IN(0)-IN(N−1). The multiplexer switching functionality is provided using N transmission gate switches like the transmission gate switch 10 shown in FIG. 1 which are selectively actuated to pass a selected one of the input signals IN and generate the output signal OUT at the output node 24.

The input 12 of each transmission gate switch 10 is coupled, preferably directly connected, to a corresponding one of the N input nodes 22(0)-22(N−1) and the outputs 14 of all transmission gate switches 10 are coupled, preferably directly connected, to the output node 24. A control bus 26 carries an N-bit channel selection signal SEL<N−1:0> that controls the selection of one of the transmission gate switches 10 to be in a closed switch condition. The bits SEL(0)-SEL(N−1) of the channel selection signal SEL<N−1:0> are connected, respectively, to provide the switch control signals SW(0)-SW(N−1) for the corresponding transmission gate switches 10(0)-10(N−1).

There remains a need in art to resolve the issue of linearity of response for the individual transmission gate switches 10 used in the analog multiplexer circuit 21. Increasing the sizes of the MOSFET devices 16 and 18 for each transmission gate switch 10 can help to a certain extent. However, this solution remains limited in practical effectiveness and performance due the negative impact on its own capacitance and a significant increase in occupied circuit area.

### SUMMARY

In an embodiment, an analog multiplexer circuit comprises: a first input; a second input; an output; a control input configured to receive first and second bits of a selection signal; a first transmission gate circuit including a first level shifting circuit coupled to receive the first bit of said selection signal and generate a first level shift selection signal, the first transmission gate circuit further including a first transmission gate switch coupled between the first input and the output; a second transmission gate circuit including a second level shifting circuit coupled to receive the second bit of said selection signal and generate a second level shift selection signal, the second transmission gate circuit further including a second transmission gate switch coupled between the second input and the output; a voltage sensing circuit configured to sense a level of a first supply voltage and generate an enable signal in response to the sensed level; and a selection circuit having a first input configured to receive the first and second bits of the selection signal and a second input configured to receive the first and second level shift selection signals, the selection circuit controlled by a first logic state of the enable signal to pass the first and second bits of the selection signal to control terminals of the first and second transmission gate switches, respectively, and further controlled by a second logic state of the enable signal to pass the first and second level shift selection signals to control terminals of the first and second transmission gate switches, respectively.

In an embodiment, an analog multiplexer circuit comprises: a first input; a second input; an output; a control input configured to receive first and second bits of a selection signal; a first transmission gate circuit including a first transmission gate switch coupled between the first input and the output, the first transmission gate circuit further including a first level shifting circuit coupled to receive the first bit of said selection signal and generate a first level shift selection signal applied to a control terminal of said first transmission gate switch; and a second transmission gate circuit including a second transmission gate switch coupled between the second input and the output, the second transmission gate circuit further including a second level shifting circuit coupled to receive the second bit of said selection signal and generate a second level shift selection signal applied to a control terminal of said second transmission gate switch.

In an embodiment, a transmission gate circuit comprises: an input; an output; a control input configured to receive a switch control signal; a transmission gate switch coupled between the input and the output; a level shifting circuit coupled to receive the switch control signal and generate a level shifted switch control signal; a voltage sensing circuit configured to sense a level of a first supply voltage and generate an enable signal in response to the sensed level; and a selection circuit having a first input configured to receive the switch control signal and a second input configured to receive the level shifted switch control signal, the selection circuit controlled by a first logic state of the enable signal to pass the switch control signal to a control terminal of the transmission gate switch, and further controlled by a second logic state of the enable signal to pass the level shifted switch control signal to the control terminal of the transmission gate switch.

In an embodiment, a transmission gate circuit comprises: an input; an output; a control input configured to receive a switch control signal; a transmission gate switch coupled between the input and the output; and a level shifting circuit coupled to receive the switch control signal and generate a level shifted switch control signal that is applied to a control terminal of said transmission gate switch.

### BRIEF DESCRIPTION OF THE DRAWINGS

For a better understanding of the embodiments, reference will now be made by way of example only to the accompanying figures in which:

FIG. 1 shows a circuit diagram for a conventional transmission gate switch;

FIG. 2 shows a plot of resistivity versus input voltage for the conventional transmission gate switch of FIG. 1;

FIG. 3 shows a circuit diagram for a conventional analog multiplexer circuit using transmission gate switches like that shown in FIG. 1;

FIG. 4 shows a circuit diagram for an embodiment of a transmission gate circuit;

FIG. 5 shows a circuit diagram for another embodiment of a transmission gate circuit;

FIG. 6 shows a circuit diagram for an analog multiplexer circuit using transmission gate switches like that shown in FIG. 4; and

FIG. 7 shows a circuit diagram for an analog multiplexer circuit using transmission gate switches like that shown in FIG. 5.

### DETAILED DESCRIPTION

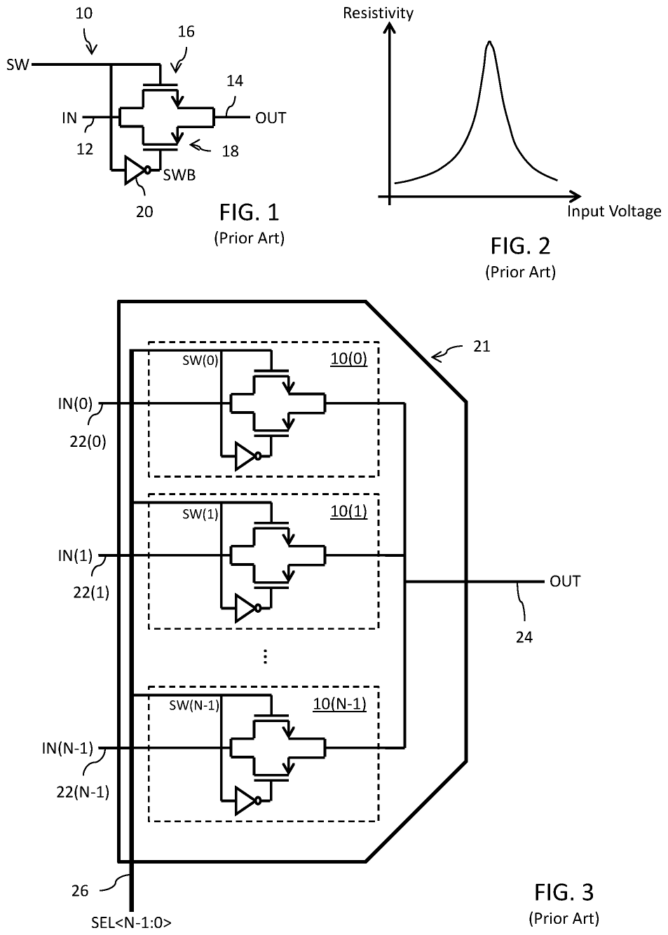

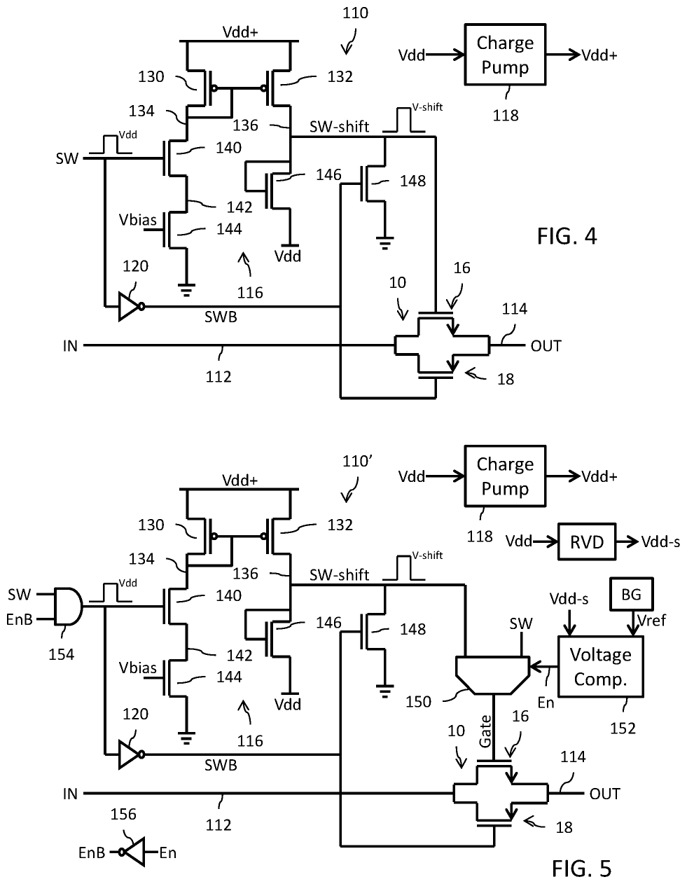

Reference is made to FIG. 4 which shows a circuit diagram for an embodiment of a transmission gate circuit 110. The circuit 110 includes an input node 112 and an output node 114 coupled to a transmission gate switch 10 (see, also FIG. 1). The input node 112 is configured to receive an input signal IN that is referenced to a supply voltage Vdd. By this it is meant that the circuitry (not explicitly shown) which generates the input signal IN is supplied with power from the supply voltage Vdd. The transmission gate switch 10 functions, in response to a selection signal (SW) to selectively pass the input signal IN to produce an output signal OUT at the output node 114.

The transmission gate switch 10 includes an n-channel metal oxide semiconductor field effect transistor (MOSFET) device 16 having a drain terminal coupled, preferably directly connected, to the input node 112 and a source terminal coupled, preferably directly connected, to the output node 114. A p-channel MOSFET device 18 of the transmission gate switch 10 has a drain terminal coupled, preferably directly connected, to the input node 112 and a source terminal coupled, preferably directly connected, to the output node 114. The MOSFET devices 16 and 18 are, thus, connected in parallel with each other.

The switching operation of the transmission gate switch 10 is controlled by a switch control (selection) signal SW. A level shifter circuit 116 level shifts the switch control signal SW to generate a shifted switch control signal SW-shift. The level shifting operation performed by the level shifter circuit 116 shifts a logic high voltage level of the switch control signal SW from a first supply voltage level Vdd to a shifted voltage level V-shift (where V-shift>Vdd) in response to a second supply voltage level Vdd+(where Vdd+>Vdd). The second supply voltage level Vdd+ may be generated from the first supply voltage level Vdd using a charge pump circuit 118. The gate terminal of the n-channel MOSFET device 16 is coupled to receive the level shifted switch control signal SW-shift. The gate terminal of the p-channel MOSFET device 18 is coupled to receive a logical inverse (SWB) of the switch control signal SW. The logical inverse switch control signal SWB may be generated, for example, by a logical inverter circuit 120 from the switch control signal SW.

Operation of the circuit 110 is as follows: in response to the switch control signal SW in a first (for example, low) logic state, the shifted switch control signal SW-shift is also logic low (at the ground voltage level) and the logical inverse switch control signal SWB is logic high (at the Vdd voltage level). The transistors 16 and 18 are both turned off, and the transmission gate switch 10 functions as an open switch blocking passage of the input signal IN at the input node 112 from reaching the output node 114. Conversely, in response to the switch control signal SW in a second (for example, high) logic state, the shifted switch control signal SW-shift is in a logic high state (at the V-shift voltage level, where Vdd+≥V-shift>Vdd) and the logical inverse switch control signal SWB is logic low (at the ground voltage level). The transistors 16 and 18 are both turned on, and the transmission gate switch 10 functions as a closed switch permitting passage of the input signal IN at the input node 112 to produce the output signal OUT at the output node 114.

The level shifter circuit 116 includes a first p-channel MOSFET device 130 and a second p-channel MOSFET device 132 connected in a current mirroring configuration. The sources of devices 130 and 132 are coupled, preferably directly connected, to a supply voltage node (for example, coupled to the output of the charge pump circuit 118) providing the second supply voltage level Vdd+. The gates of devices 130 and 132 are coupled, preferably directly connected, to the drain of the device 130 at node 134. A first n-channel MOSFET device 140 has a drain coupled, preferably directly connected, to node 134, a source coupled, preferably directly connected, to a node 142 and a gate configured to receive the switch control signal SW. A second n-channel MOSFET device 144 has a drain coupled, preferably directly connected, to node 142, a source coupled, preferably directly connected, to the ground node and a gate configured to receive a bias voltage Vbias (derived, for example, from Vdd or a bandgap reference). A shift voltage setting circuit 146 formed by a third n-channel MOSFET device has a drain coupled, preferably directly connected, to node 136, a source coupled, preferably directly connected, to a supply voltage node providing the first supply voltage level Vdd. A fourth n-channel MOSFET device 148 has a drain coupled, preferably directly connected, to node 136, a source coupled, preferably directly connected, to the ground node and a gate configured to receive the logical inverse switch control signal SWB from the output of the logical inverter circuit 120. The level shifted switch control signal SW-shift is output from node 136 and applied to the gate of the MOSFET device 16.

Although shift voltage setting circuit 146 is shown as an n-channel MOSFET in a diode-connected configuration, it will be understood that the shift voltage setting circuit 146 could instead be a diode-connected p-channel MOSFET. Alternatively, shift voltage setting circuit 146 could be a resistor circuit, or a series connection of one or more of: a resistor, a diode, a MOSFET device. The function of shift voltage setting circuit 146 is to set the level of the shift voltage V-shift in response to the applied current from the output of the current mirror, and those skilled in the art are well aware of circuit configurations suited for this function.

The first and second n-channel MOSFET devices 140 and 144 function as a switchable current source circuit generating a switched current in response to the logic state of the switch control signal SW. That switched current is mirrored by the current mirror circuit formed by first and second p-channel MOSFET devices 130 and 132 to apply an output current to the third n-channel MOSFET device 146 when the switch control signal SW is asserted. The voltage drop across shift voltage setting circuit 146 in response to the output current sets the shifted voltage level V-shift at node 136 for the shifted switch control signal SW-shift. In this configuration, the logic high voltage level for the shifted switch control signal SW-shift would equal one gate-to-source voltage (of the diode-connected n-channel MOSFET for the shift voltage setting circuit 146) above the supply voltage Vdd. The output current further charges the gate capacitance of the MOSFET device 16 when the switch control signal SW is asserted. Application of the shifted voltage level V-shift, at least to the n-channel MOSFET device 16, when configuring the transmission gate switch 10 as a closed switch improves transmission gate 10 performance. The fourth n-channel MOSFET device 148 responds to assertion of the logical inverse switch control signal SWB to discharge the gate capacitance of the MOSFET device 16 when configuring the transmission gate switch 10 as an open switch. This also ensures that the logic low voltage level for the shifted switch control signal SW-shift is at ground.

The transmission gate circuit 110 of FIG. 4 provides acceptable performance in many circuit applications, with the voltage level for the shifted voltage level V-shift being higher than the referenced supply voltage Vdd for the input signal IN contributing to improved response linearity.

Reference is made to FIG. 5 which shows a circuit diagram for an embodiment of a transmission gate circuit 110′. Like references in FIGS. 4 and 5 refer to same circuit components. The circuit 110′ differs from the circuit 110 in the addition of a multiplexer 150, a voltage comparator 152 and a logic gate 154. The multiplexer 150 has a first input configured to receive the shifted switch control signal SW-shift from node 136 and a second input configured to receive the switch control signal SW. The multiplexer 150 functions to select which one of the shifted switch control signal SW-shift and the switch control signal SW is applied as a gate control signal (Gate) to the gate of the MOSFET device 16 in response to an enable signal En generated by the voltage comparator 152. The voltage comparator 152 has a first input configured to receive a scaled version (Vdd-s) of the supply voltage Vdd (for example, generated using a resistive voltage divider circuit RVD) and a second input configured to receive a reference voltage Vref (for example, generated using a band-gap voltage generator circuit BG). The scaled supply voltage Vdd-s is compared to the reference voltage Vref. When Vdd-s<Vref, the enable signal En is asserted (logic low, for example) by the voltage comparator 152, and the multiplexer 150 responds by selecting the shifted switch control signal SW-shift for application as the Gate signal to the gate of the MOSFET device 16. Conversely, when Vdd-s≥Vref, the enable signal En is deasserted by the voltage comparator 152 and the multiplexer 150 responds by selecting the switch control signal SW for application as the Gate signal to the gate of the MOSFET device 16. The scaling provided by voltage divider circuit RVD to generate the scaled supply voltage Vdd-s is selected so that the enable signal En will be asserted only when the level of the supply voltage Vdd is below a point where satisfactory operation of the transmission gate switch 10 is possible in the absence of the use of the higher voltage level associated with the shifted switch control signal SW-shift. Thus, when the supply voltage Vdd is sufficiently high, the transmission gate circuit 110 utilizes the switch control signal SW to control the MOSFET device 16, and issues with leakage current and switching noise are obviated. However, when the supply voltage Vdd is insufficient (for example, due to battery drain), the transmission gate circuit 110 utilizes the shifted switch control signal SW-shift to control the MOSFET device 16.

The logic gate 154 logically ANDs the switch control signal SW with a logical inverse (EnB) of the enable signal En (generated by a logic inverter 156). The logic gate 154 accordingly functions as a circuit for gating the switch control signal SW dependent on the logic state of the enable signal En. When the enable signal En is asserted logic low, the inverse enable signal EnB is logic high and the AND logic gate 154 will pass the switch control signal SW for level shifting to generate the shifted switch control signal SW-shift which is selected by the multiplexer 150 and applied to the gate of the MOSFET device 16. Conversely, when Vdd-s≥Vref, the enable signal En is deasserted, the inverse enable signal EnB is logic low and the AND logic gate 154 blocks the switch control signal SW from being level shifted, with the switch control signal SW being selected by the multiplexer 150 and applied to the gate of the MOSFET device 16.

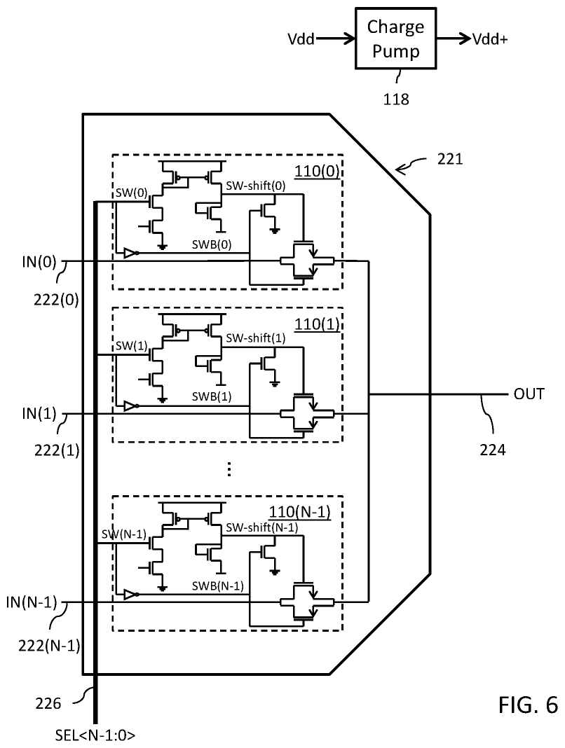

Reference is now made to FIG. 6 which shows a circuit diagram for an analog multiplexer (MUX) circuit 221 that uses selectively actuated transmission gate switches. The circuit 221 includes N input nodes 222(0)-222(N−1) and an output node 224. Each input node 222 is configured to receive a corresponding analog input signal IN(0)-IN(N−1). The multiplexer switching functionality is provided using N transmission gate circuits 110 like the transmission gate circuits 110 shown in FIG. 4 which are selectively actuated to pass a selected one of the input signals IN and generate the output signal OUT at the output node 224.

The input 112 of each transmission gate circuit 110 is coupled, preferably directly connected, to a corresponding one of the N input nodes 222(0)-222(N−1) and the outputs 114 of all transmission gate circuits 110 are coupled, preferably directly connected, to the output node 224. A control bus 226 carries an N-bit channel selection signal SEL<N−1:0> that controls the selection of one of the transmission gate switches 10 to be in a closed switch condition. The bits SEL(0)-SEL(N−1) of the channel selection signal SEL<N−1:0> are connected, respectively, to provide the switch control signals SW(0)-SW(N−1) for the corresponding transmission gate circuits 110(0)-110(N−1).

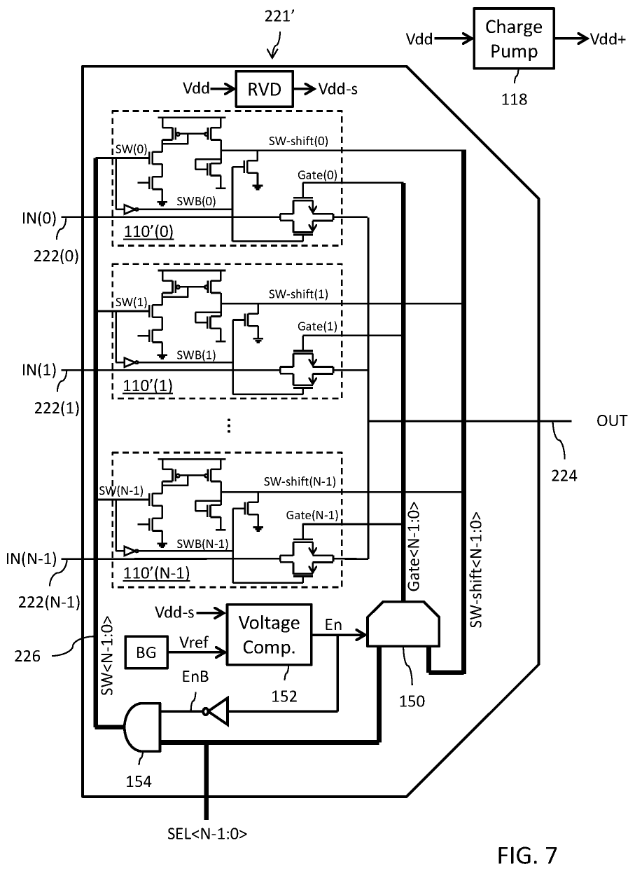

Reference is now made to FIG. 7 which shows a circuit diagram for an analog multiplexer (MUX) circuit 221′ that uses selectively actuated transmission gate switches. The circuit 221′ includes N input nodes 222(0)-222(N−1) and an output node 224. Each input node 222 is configured to receive a corresponding analog input signal IN(0)-IN(N−1). The multiplexer switching functionality is provided using N transmission gate circuits 110′ like the transmission gate circuits 110′ shown in FIG. 5 which are selectively actuated to pass a selected one of the input signals IN and generate the output signal OUT at the output node 224.

The input 112 of each transmission gate circuit 110′ is coupled, preferably directly connected, to a corresponding one of the N input nodes 222(0)-222(N−1) and the outputs 114 of all transmission gate circuits 110′ are coupled, preferably directly connected, to the output node 224. A control bus 226 carries an N-bit switch signal SW<N−1:0> that controls the selection of one of the transmission gate switches 10 to be in a closed switch condition. The bits of the N-bit switch signal SW<N−1:0> are connected, respectively, to provide the switch control signals SW(0)-SW(N−1) for the corresponding transmission gate circuits 110′(0)-110′(N−1).

An N-bit channel selection signal SEL<N−1:0> that controls the selection of one of the transmission gate switches 10 to be in a closed switch condition is received by the circuit 221′ and applied to an input of a logic gate 154. The logic gate 154 logically ANDs the N-bit channel selection signal SEL<N−1:0> with a logical inverse (EnB) of an enable signal En. The logic gate 154 accordingly functions as a circuit for gating the N-bit channel selection signal SEL<N−1:0> dependent on the logic state of the enable signal En. When the enable signal En is asserted logic low, the inverse enable signal EnB is logic high and the AND logic gate 154 will pass the N-bit channel selection signal SEL<N−1:0> to provide the N-bit switch signal SW<N−1:0> for level shifting by the transmission gate circuits 110′. Conversely, when the enable signal En is asserted logic high, the inverse enable signal EnB is logic low and the AND logic gate 154 will block passage of the N-bit channel selection signal SEL<N−1:0>.

The enable signal En is generated by a voltage comparator 152. The voltage comparator 152 has a first input configured to receive a scaled version (Vdd-s) of the supply voltage Vdd (for example, generated using a resistive voltage divider circuit RVD) and a second input configured to receive a reference voltage Vref (for example, generated using a band-gap voltage generator circuit BG). The scaled supply voltage Vdd-s is compared to the reference voltage Vref. When Vdd-s<Vref, the enable signal En is asserted (logic low, for example) by the voltage comparator 152. Conversely, when Vdd-s≥Vref, the enable signal En is deasserted by the voltage comparator 152.

The N-bit channel selection signal SEL<N−1:0> is further applied to an input of a multiplexer 150. A further input of the multiplexer 150 receives an N-bit shifted switch control signal SW-shift<N−1:0> formed by the shifted switch control signals SW-shift(0)-SW-shift(N−1) generated, respectively, by the transmission gate circuits 110′(0)-110′(N−1). The multiplexer 150 functions to select which one of the N-bit shifted switch control signal SW-shift<N−1:0> or the N-bit channel selection signal SEL<N−1:0> is applied as an N-bit gate control signal Gate<N−1:0> to the gates of the MOSFET devices 16 of the transmission gate switches 10 in circuits 110′(0)-110′(N−1) in response to the enable signal En generated by the voltage comparator 152. When the enable signal En is asserted logic low (i.e., because Vdd-s<Vref), the multiplexer 150 passes the N-bit shifted switch control signal SW-shift<N−1:0> as the N-bit gate control signal Gate<N−1:0>. Conversely, when the enable signal En is deasserted logic high (i.e., because Vdd-s≥Vref), the multiplexer 150 passes the N-bit channel selection signal SEL<N−1:0> as the N-bit gate control signal Gate<N−1:0>.

The scaling provided by voltage divider circuit RVD to generate the scaled supply voltage Vdd-s is selected so that the enable signal En will be asserted only when the level of the supply voltage Vdd is below a point where satisfactory operation of the transmission gate switches 10 is possible in the absence of the use of the higher voltage level associated with the shifted switch control signal SW-shift. Thus, when the supply voltage Vdd is sufficiently high, the transmission gate circuits 110′ utilize the N-bit channel selection signal SEL<N−1:0> as the N-bit gate control signal Gate<N−1:0> for the MOSFET devices 16. However, when the supply voltage Vdd is insufficient (for example, due to battery drain), the transmission gate circuits 110′ utilize the N-bit shifted switch control signal SW-shift<N−1:0> as the N-bit gate control signal Gate<N−1:0> for the MOSFET devices 16.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. An analog multiplexer circuit, comprising:
a first input;
a second input;
an output;
a control input configured to receive first and second bits of a selection signal;
a first transmission gate circuit including a first level shifting circuit coupled to receive the first bit of said selection signal and generate a first level shift selection signal, the first transmission gate circuit further including a first transmission gate switch coupled between the first input and the output;
a second transmission gate circuit including a second level shifting circuit coupled to receive the second bit of said selection signal and generate a second level shift selection signal, the second transmission gate circuit further including a second transmission gate switch coupled between the second input and the output;
a voltage sensing circuit configured to sense a level of a first supply voltage and generate an enable signal in response to the sensed level; and
a selection circuit having a first input configured to receive the first and second bits of the selection signal and a second input configured to receive the first and second level shift selection signals, the selection circuit controlled by a first logic state of the enable signal to pass the first and second bits of the selection signal to control terminals of the first and second transmission gate switches, respectively, and further controlled by a second logic state of the enable signal to pass the first and second level shift selection signals to control terminals of the first and second transmission gate switches, respectively.

2. The circuit of claim 1, wherein the first and second inputs are configured to receive first and second input signals referenced to said first supply voltage.

3. The circuit of claim 1, wherein the first and second transmission gate circuits are powered by a second supply voltage that is greater than said first supply voltage.

4. The circuit of claim 3, further comprising a charge pump circuit configured to generate said second supply voltage from said first supply voltage.

5. The circuit of claim 3, wherein said first and second level shift selection signals have a logic high voltage that is greater than said first supply voltage.

6. The circuit of claim 3, wherein said first and second level shift selection signals have a logic high voltage that is less than or equal to said second supply voltage.

7. The circuit of claim 1, wherein each of the first and second transmission gate switches comprises an n-channel metal oxide semiconductor field effect transistor (MOSFET) having a gate terminal configured to receive output from the selection circuit.

8. The circuit of claim 7, wherein each of the first and second transmission gate switches further comprises a parallel connected p-channel MOSFET having a gate terminal configured to receive a logical inversion of the respective bit of the selection signal.

9. The circuit of claim 1, further comprising a logical pass gate circuit having a first input configured to receive the first and second bits of the selection signal, a second input configured to receive the enable signal, and an output coupled to inputs of the first and second level shifting circuits.

10. The circuit of claim 9, wherein said logical pass gate circuit is a logical AND gate.

11. The circuit of claim 1, wherein the voltage sensing circuit comprises a voltage comparator configured to compare a voltage derived from said first supply voltage to a reference voltage and generate said enable signal in response to the comparison.

12. The circuit of claim 11, wherein the reference voltage comprises a bandgap voltage.

13. The circuit of claim 11, wherein the voltage derived from said first supply voltage is generated by a voltage divider circuit.

14. A transmission gate circuit, comprising:
an input;
an output;
a control input configured to receive a switch control signal;
a transmission gate switch coupled between the input and the output;
a level shifting circuit coupled to receive the switch control signal and generate a level shifted switch control signal;
a voltage sensing circuit configured to sense a level of a first supply voltage and generate an enable signal in response to the sensed level; and
a selection circuit having a first input configured to receive the switch control signal and a second input configured to receive the level shifted switch control signal, the selection circuit controlled by a first logic state of the enable signal to pass the switch control signal to a control terminal of the transmission gate switch, and further controlled by a second logic state of the enable signal to pass the level shifted switch control signal to the control terminal of the transmission gate switch.

15. The circuit of claim 14, wherein the input is configured to receive an input signal referenced to said first supply voltage, wherein the level shifting circuit is powered by a second supply voltage that is greater than said first supply voltage; and wherein said level shifted switch control signal has a logic high voltage that is greater than said first supply voltage.

16. The circuit of claim 15, further comprising a charge pump circuit configured to generate said second supply voltage from said first supply voltage.

17. The circuit of claim 15, wherein the logic high voltage of said level shifted switch control signal is less than or equal to said second supply voltage.

18. The circuit of claim 14, wherein the transmission gate switch comprises an n-channel metal oxide semiconductor field effect transistor (MOSFET) having a gate terminal configured to receive the level shifted switch control signal.

19. The circuit of claim 18, wherein the transmission gate switch further comprises a parallel connected p-channel MOSFET having a gate terminal configured to receive a logical inversion of the switch control signal.

20. The circuit of claim 14, further comprising a logical pass gate circuit having a first input configured to receive the switch control signal, a second input configured to receive the enable signal, and an output coupled to an inputs of the level shifting circuit.

21. The circuit of claim 20, wherein said logical pass gate circuit is a logical AND gate.

22. The circuit of claim 14, wherein the voltage sensing circuit comprises a voltage comparator configured to compare a voltage derived from said first supply voltage to a reference voltage and generate said enable signal in response to the comparison.

23. The circuit of claim 22, wherein the reference voltage comprises a bandgap voltage.

24. The circuit of claim 22, wherein the voltage derived from said first supply voltage is generated by a voltage divider circuit.

25. An analog multiplexer circuit, comprising:
a first input;
a second input;
an output;
a control input configured to receive first and second bits of a selection signal;
a first transmission gate circuit including a first transmission gate switch coupled between the first input and the output, the first transmission gate circuit further including a first level shifting circuit coupled to receive the first bit of said selection signal and generate a first level shift selection signal applied to a control terminal of said first transmission gate switch; and
a second transmission gate circuit including a second transmission gate switch coupled between the second input and the output, the second transmission gate circuit further including a second level shifting circuit coupled to receive the second bit of said selection signal and generate a second level shift selection signal applied to a control terminal of said second transmission gate switch.

26. The circuit of claim 25, wherein the first and second inputs are configured to receive first and second input signals referenced to a first supply voltage.

27. The circuit of claim 26, wherein the first and second transmission gate circuits are powered by a second supply voltage that is greater than said first supply voltage.

28. The circuit of claim 27, further comprising a charge pump circuit configured to generate said second supply voltage from said first supply voltage.

29. The circuit of claim 27, wherein said first and second level shift selection signals have a logic high voltage that is greater than said first supply voltage.

30. The circuit of claim 27, wherein said first and second level shift selection signals have a logic high voltage that is less than or equal to said second supply voltage.

31. The circuit of claim 25, wherein each of the first and second transmission gate switches comprises an n-channel metal oxide semiconductor field effect transistor (MOSFET) having a gate terminal configured to receive the respective level shift selection signal.

32. The circuit of claim 31, wherein each of the first and second transmission gate switches further comprises a parallel connected p-channel MOSFET having a gate terminal configured to receive a logical inversion of the respective bit of the selection signal.

33. A transmission gate circuit, comprising:
an input;
an output;
a control input configured to receive a switch control signal;
a transmission gate switch coupled between the input and the output; and
a level shifting circuit coupled to receive the switch control signal and generate a level shifted switch control signal that is applied to a control terminal of said transmission gate switch.

34. The circuit of claim 33, wherein the input is configured to receive an input signal referenced to a first supply voltage, wherein the level shifting circuit is powered by a second supply voltage that is greater than said first supply voltage; and wherein said level shifted switch control signal has a logic high voltage that is greater than said first supply voltage.

35. The circuit of claim 34, further comprising a charge pump circuit configured to generate said second supply voltage from said first supply voltage.

36. The circuit of claim 34, wherein the logic high voltage of said level shifted switch control signal is less than or equal to said second supply voltage.

37. The circuit of claim 33, wherein the transmission gate switch comprises an n-channel metal oxide semiconductor field effect transistor (MOSFET) having a gate terminal configured to receive the level shifted switch control signal.

38. The circuit of claim 37, wherein the transmission gate switch further comprises a parallel connected p-channel MOSFET having a gate terminal configured to receive a logical inversion of the switch control signal.
